(19) United States
(12) Patent Application Publication
(10) Pub. No.: US 2026/0259263 A1
(43) Pub. Date: Sep. 3, 2026

(54) SCAN TEST IN A SINGLE-WIRE BUS CIRCUIT

(71) Applicant: Qorvo US, Inc., Greensboro, NC (US)

(72) Inventors: James Mark Robert Bloom, San Tan Valley, AZ (US); Christopher Truong Ngo, Queen Creek, AZ (US)

(21) Appl. No.: 19/162,476

(22) PCT Filed: Feb. 28, 2024
(86) PCT No.: PCT/US2024/017646

§ 371 Date: Sep. 5, 2025

Related U.S. Application Data
(60) Provisional application No. 63/450,786, filed on Mar. 8, 2023.

(51) Int. Cl. G01R 31/3185

(52) U.S. Cl. CPC G01R 31/318572; G01R 31/318552

(57) ABSTRACT

A Scan test in a single-wire bus circuit is described in the present disclosure. The single-wire bus circuit has one or more external pins for connecting to a single-wire bus. Given that multiple physical pins are required to carry out the Scan test, the single-wire bus circuit must provide additional pins required by the Scan test. In embodiments disclosed herein, the single-wire bus circuit includes a communication circuit under test and a driver circuit coupled to the communication circuit via multiple internal pins. The driver circuit uses a subset of the internal pins as input pins and another subset of the internal pins as output pins in order to carry out the Scan test in the communication circuit. A mini-telegram is sent at the beginning of the Scan test along with common bus values. This reduces the time required to perform the scan test.

### RELATED APPLICATIONS

This application claims the benefit of provisional patent application Ser. No. 63/450,786, filed Mar. 8, 2023, the disclosure of which is hereby incorporated herein by reference in its entirety.

### FIELD OF THE DISCLOSURE

The technology of the disclosure relates generally to performing a Scan test in a single-wire bus circuit exposing only one physical pin.

### BACKGROUND

Mobile communication devices have become increasingly common in current society. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

Today's mobile communication devices can include numerous logic devices. As the logic devices become increasingly complex, it will take tremendous amounts of time and effort to manually create, execute, and validate the logic devices based on traditional testing methods (a.k.a., functional tests). Further, the functional tests can only exercise expected modes of operation on certain parts, as opposed to exercising all possible modes of operation on all parts in the logic devices. Those unexercised modes of operation on those untested parts can become problematic when the untested parts are made to operate in an unexpected mode(s), or with undetected flows that cause the untested parts to behave intermittently or draw excess supply current. To overcome deficiency of the traditional testing methods, a design for test (DFT) approach, wherein an integrated circuit (IC) design is modified to accommodate structural tests (a.k.a., Scan test), has been widely adopted by the IC industry nowadays.

A Scan test is a well-known method that involves scanning test patterns into internal circuits within the logic devices under test. FIG. 1 is a schematic diagram of an exemplary circuit 10 configured to perform a Scan test on a combinational logic 12. The circuit 10 includes one or more register circuits 14 (e.g., flip-flop circuits) that are coupled to the combinational logic 12 via one or more two-to-one multiplexers 16.

In a normal operation, the combinational logic 12 receives one or more digital inputs 18 and outputs one or more digital outputs 20. The multiplexer 16 in front of each of the register circuits 14 takes a respective one of the digital inputs 18 from the combinational logic 12. Notably, the input to the multiplexer 16 is usually an arbitrary logic gate (not shown) output within the combinational logic 12 and is not necessarily the digital input 18. Each of the register circuits 14 drives the combinational logic 12 to output a respective one of the digital outputs 20. The output of the register circuits 14 is usually an input to a logic gate (not shown) within the combinational logic 12 and not necessarily the digital output 20.

In Scan test mode, the multiplexers 16 are switched so that the register circuits 14 operate as large shift registers. To perform the Scan test, a known data pattern is first loaded into the register circuits 14 via a Scan input (SI) pin in accordance with a clock (CLK) signal (not shown) received via a CLK pin. Once the data pattern is loaded into the register circuits 14, then a Scan enable (SE) is set on an SE pin to switch the multiplexers 16 out of the Scan test mode and back to operational mode to thereby propagate the data residing in the register circuits 14 through the combinational logic 12. After the logic states have settled, then the SE toggles the multiplexers 16 back to the Scan test mode and the data is clocked out of the register circuits 14 via a Scan output (SO) pin. In this regard, it would require a minimum of four (4) physical pins, namely the SI pin, the SE pin, the CLK pin, and the SO pin, to enable the Scan test in the circuit 10.

### SUMMARY

In some embodiments, a bus circuit includes one or more bus pins coupled to a bus; a communication circuit coupled to the bus; and a driver circuit coupled to the one or more bus pins and includes: a plurality of test pins coupled to the communication circuit; and a test driver circuit configured to operate in a test mode during a test cycle, the test driver circuit is configured to: receive a start of scan (SOS) sequence on at least one of the one or more bus pins, wherein the SOS sequence indicates a beginning of the test cycle; and receive a scan enable value on at least one of the one or more bus pins during the test cycle; receive a series of scan inputs over the one of more bus pins during the test cycle; generate sets of test inputs, wherein each set of test inputs includes a different one of the scan inputs and the scan value.

In some embodiments, the communication circuit includes a plurality of sequential state elements; each of the sequential state elements is configured to receive a different one of the sets of test inputs. In some embodiments, the communication circuit further includes combinational logic; the test driver circuit is further configured to receive a series of test outputs, each test output resulting from a previous set of test inputs being processed by the combinational logic. In some embodiments, the one or more bus pins is a single bus pin; the bus is a single-wire bus; the test driver circuit is configured to generate a device clock in accordance with pulses received on the single bus pin and transmit the device clock to the communication circuit. In some embodiments, the one or more bus pins is a single bus pin; the bus is a single-wire bus; the test driver circuit includes an oscillator that generates a clock signal; the test driver circuit is configured to generate a device clock in accordance with clock signal from the oscillator and transmit the device clock to the communication circuit. In some embodiments, the one or more bus pins includes a data pin and a clock pin; wherein the SOS sequence, the scan enable value, and the sets of test inputs are configured to be received on the data pin; a clock pin is configured to receive a clock signal; the test driver circuit is configured to generate a device clock in accordance with clock signal and transmit the device clock to the communication circuit. In some embodiments, the test driver circuit configured to operate in the test mode during the test cycle, the test driver circuit is configured to: receive a scan reset value on at least one of the one or more bus pins during the test cycle; generate the sets of test inputs such that each set of test inputs includes the scan reset value. In some embodiments, the bus is a single-wire bus and the one or more bus pins are a single bus pin and the bus circuit further includes: a switch circuit coupled between the bus pin, the communication circuit, and the test driver circuit; and a driver controller configured to: control the switch circuit to decouple the communication circuit from the bus pin and to couple the test driver circuit to the bus pin in response to the SOS sequence; and control the switch circuit to decouple the test driver circuit from the bus pin and to couple the communication circuit in response to an explicit indication of a communication mode. In some embodiments, the driver circuit further includes a test mode pin coupled between the driver controller and the communication circuit; and the communication circuit is configured to assert the test mode pin to provide the explicit indication of the test mode and de-assert the test mode pin to provide the explicit indication of the communication mode. In some embodiments, the communication circuit includes a mode detector configured to: assert the test mode pin in response to receiving a test initiation command; and de-assert the test mode pin in response to power cycling of the bus circuit. In some embodiments, the communication circuit includes a receive circuit coupled to the bus pin and is configured to: receive the test initiation command in the communication mode via the bus pin; and provide the test initiation command to the mode detector.

In some embodiments, a single-wire bus circuit includes: the bus pin coupled to a single-wire bus; a communication circuit coupled to the single-wire bus; and a driver circuit coupled to the one or more bus pins and includes: a plurality of test pins coupled to the communication circuit; and a test driver circuit configured to operate in a test mode during a test cycle, the test driver circuit is configured to: receive a start of scan (SOS) sequence on the single-wire bus pin, wherein the SOS sequence indicates a beginning of the test cycle; and receive a scan enable value on the bus pin during the test cycle; receive a series of scan inputs on the bus pin during the test cycle; generate sets of test inputs, wherein each set of test inputs includes a different one of the scan inputs and the scan value.

In some embodiments, the communication circuit includes a plurality of sequential state elements; each of the sequential state elements is configured to receive a different one of the sets of test inputs. In some embodiments, the communication circuit further includes combinational logic; the test driver circuit is further configured to receive a series of test outputs, each test output resulting from a previous set of test inputs being processed by the combinational logic. In some embodiments, the test driver circuit is further configured to transmit the sets of test inputs to the communication circuit through the plurality of test pins. In some embodiments, the plurality of test pins further includes a scan output pin to receive scan output from the communication circuit. In some embodiments, the single-wire bus, further includes a switch circuit coupled between the bus pin, the communication circuit, and the test driver circuit; and a driver controller configured to: control the switch circuit to decouple the communication circuit from the bus pin and to couple the test driver circuit to the bus pin in response to the SOS sequence; and control the switch circuit to decouple the test driver circuit from the bus pin and to couple the communication circuit in response to an explicit indication of a communication mode. In some embodiments, the driver circuit further includes a test mode pin coupled between the driver controller and the communication circuit; and the communication circuit is configured to assert the test mode pin to provide the explicit indication of the test mode and de-assert the test mode pin to provide the explicit indication of the communication mode. In some embodiments, the communication circuit includes a mode detector configured to: assert the test mode pin in response to receiving a test initiation command; and de-assert the test mode pin in response to power cycling of the bus circuit. In some embodiments, the SOS sequence includes a pulse having a duration of at least two bus symbols.

Those skilled in the art will appreciate the scope of the disclosure and realize additional aspects thereof after reading the following detailed description in association with the accompanying drawings.

### BRIEF DESCRIPTION OF THE DRAWING FIGURES

The accompanying drawings incorporated in and forming a part of this specification illustrate several aspects of the disclosure and, together with the description, serve to explain the principles of the disclosure.

FIG. 1 is a schematic diagram of an exemplary circuit configured to perform a Scan test on a combinational logic;

FIG. 2A is a schematic diagram of an exemplary single-wire bus apparatus in which a master circuit is configured to communicate with slave circuit(s) over a single-wire bus consisting of a single wire;

FIG. 2B is a schematic diagram providing an exemplary illustration of a voltage pulse-width modulation (PWM) value representing a binary zero (“0”);

FIG. 2C is a schematic diagram providing an exemplary illustration of a voltage PWM value representing a binary one (“1”);

FIG. 3 is a schematic diagram of an exemplary single-wire bus circuit that can be adapted according to various embodiments of the present disclosure to enable a Scan test, despite the single-wire bus circuit only exposing a bus pin for external access via a single-wire bus;

FIG. 4 is a schematic diagram of an exemplary single-wire bus circuit, which is adapted from the single-wire bus circuit of FIG. 3, according to an embodiment of the present disclosure to support the Scan test;

FIG. 5 is a graphic diagram providing an exemplary illustration of the Scan test performed by the single-wire bus circuit of FIG. 4, in accordance with one embodiment of the present disclosure;

FIG. 6 is a graphic diagram providing an exemplary illustration of the Scan test performed by the single-wire bus circuit of FIG. 4, in accordance with an alternative embodiment of the present disclosure;

FIG. 7A of is a graphic diagram providing an exemplary illustration of the Scan test performed by the single-wire bus circuit of FIG. 4, in accordance with another embodiment of the present disclosure;

FIG. 7B is a graphic diagram providing an exemplary illustration of the Scan test performed by the single-wire bus circuit FIG. 4, in accordance with another embodiment of the present disclosure;

FIG. 8 is a graphic diagram providing an exemplary illustration of the Scan test performed by the single-wire bus circuit of FIG. 4, in accordance with another embodiment of the present disclosure;

FIG. 9 is a graphic diagram providing an exemplary illustration of the Scan test performed by the single-wire bus circuit of FIG. 4, in accordance with another embodiment of the present disclosure;

FIG. 10 is a graphic diagram providing an exemplary illustration of the Scan test performed by the single-wire bus circuit of FIG. 4, in accordance with another embodiment of the present disclosure;

FIG. 11 is a schematic diagram of an exemplary bus circuit, in accordance with some embodiments of the present disclosure;

FIG. 12 is a graphic diagram providing an exemplary illustration of the Scan test performed by the bus circuit of FIG. 11, in accordance with another embodiment of the present disclosure; and

FIG. 13 is a graphic diagram providing an exemplary illustration of the Scan test performed by the bus circuit of FIG. 11, in accordance with another embodiment of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description are related to a Scan test in a single-wire bus circuit. Specifically, the single-wire bus circuit has only one external pin for connecting to a single-wire bus. Given that multiple physical pins, namely a Scan input (SI) pin, a Scan enable (SE) pin, a clock (CLK) pin, and a Scan output (SO) pin, are required to carry out the Scan test, the single-wire bus circuit must provide additional pins required by the Scan test. In embodiments disclosed herein, the single-wire bus circuit includes a communication circuit under test, and a driver circuit coupled to the communication circuit via multiple internal pins. The driver circuit uses a subset of the internal pins as input pins (e.g., SI, SE, and CLK pins) and another subset of the internal pins as output pins (e.g., SO pins) to carry out the Scan test in the communication circuit. As a result, it is possible to perform the Scan test without adding additional external pins to the single-wire bus circuit, thus helping to reduce complexity and footprint of the single-wire bus circuit.

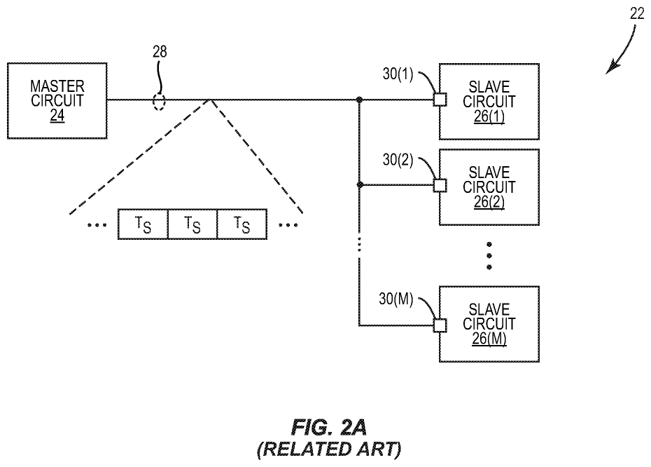

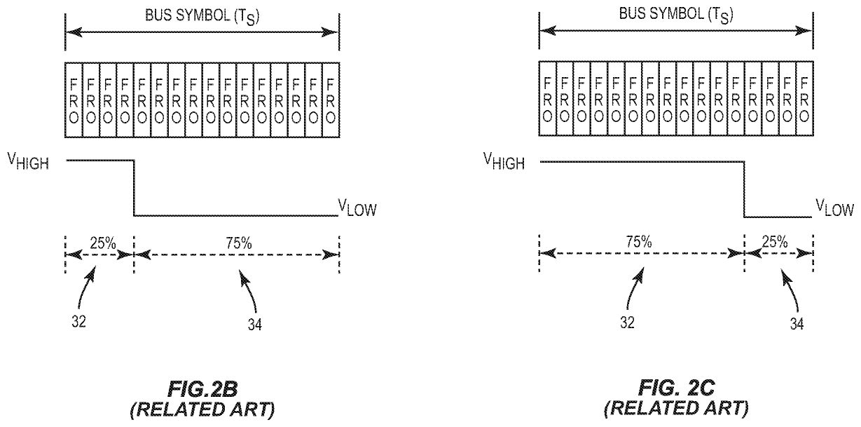

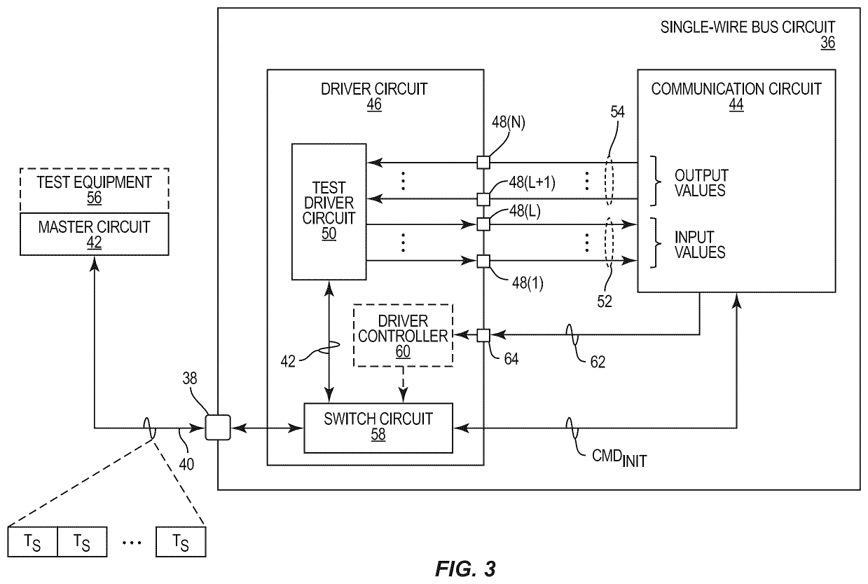

Before discussing performing a Scan test in a single-wire bus circuit of the present disclosure, starting at FIG. 3, a brief overview of a single-wire bus apparatus is first provided with reference to FIGS. 2A-2C to help understand basic operations of the single-wire bus.

In this regard, FIG. 2A is a schematic diagram of an exemplary single-wire bus apparatus 22 in which a master circuit 24 is configured to communicate with a number of slave circuits 26(1)-26(M) over a single-wire bus 28 consisting of a single wire. Each of the slave circuits 26(1)-26(M) is coupled to the single-wire bus 28 via a respective one of multiple bus pins 30(1)-30(M). Notably, the bus pins 30(1)-30(M) are the only physical pins exposed by the slave circuit 26(1)-26(M) for external access.

The master circuit 24 is configured to always initiate a bus telegram communication over the single-wire bus 28 by communicating a bus telegram(s) to one or more of the slave circuits 26(1)-26(M). As such, the single-wire bus apparatus 22 is also known as a “master-slave bus architecture.” The slave circuits 26(1)-26(M) may provide a data payload(s) to the master circuit 24 over the single-wire bus 28 in response to receiving the bus telegram(s) from the master circuit 24.

The bus telegram(s) and the data payload(s) are communicated between the master circuit 24 and the slave circuits 26(1)-26(M) based on a series of bus symbols Tₛ conveyed sequentially over the single-wire bus 28. Some of the bus symbols T_{S} are used exclusively for one-way communication from the master circuit 24 to the slave circuits 26(1)-26(M) (also referred to as “write data symbols”), while some other bus symbols T_{S} can be shared for two-way communication between the master circuit 24 and the slave circuits 26(1)-26(M) (also referred to as “read data symbols”). For a detailed description on how the master circuit 24 and the slave circuits 26(1)-26(M) can conduct one-way or two-way communication in the bus symbols T_{S}, please refer to U.S. patent application Ser. No. 17/102,510, entitled “FULL-DUPLEX COMMUNICATIONS OVER A SINGLE-WIRE BUS” (hereinafter referred to as “APP510”), which is incorporated herein in its entirety.

Each of the bus symbols T_{S} can be pulse-width modulated to represent a binary zero (“0”) or a binary one (“1”), as illustrated in FIGS. 2B and 2C, respectively. FIG. 2B is a schematic diagram providing an exemplary illustration of a voltage pulse-width modulation (PWM) value representing a binary “0.”

The bus symbol T_{S} is modulated based on a predefined high-voltage interval 32 and a predefined low-voltage interval 34 that are configured according to a predefined duty cycle. To represent the binary “0,” the predefined high-voltage interval 32 is shorter than the predefined low-voltage interval 34. For example, the bus symbol T_{S} can include sixteen (16) free-running oscillators (FROs) or 16 digitally controlled oscillators (DCOs). To represent the binary “0,” the predefined high-voltage interval 32 is configured to last for the first four (4) FROs or DCOs (25%) and the predefined low-voltage interval 34 is configured to last for the remaining twelve (12) FROs or DCOs (75%). Accordingly, the predefined duty cycle is said to be 25%. In this regard, to modulate the bus symbol T_{S} to represent the binary “0,” a higher bus voltage V_{HIGH} is first asserted on the single-wire bus 28 for 25% duration of the bus symbol T_{S} and then a lower bus voltage V_{LOW} is asserted on the single-wire bus 28 for 75% duration of the bus symbol T_{S}. Notably, the bus symbol T_{S} can also be modulated to represent the binary “0” by configuring the predefined low-voltage interval 34 to last for the first 12 FROs or DCOs (75%) and the predefined high-voltage interval 32 to last for the remaining 4 FROs or DCOs (25%).

FIG. 2C is a schematic diagram providing an exemplary illustration of a voltage PWM value representing a binary “1.” Common elements between FIGS. 2B and 2C are shown therein with common element numbers and will not be re-described herein.

To represent the binary “1,” the predefined high-voltage interval 32 is longer than the predefined low-voltage interval 34. Based on the same example in FIG. 2B, the predefined high-voltage interval 32 lasts for the first 12 FROs or DCOs (75%) and the predefined low-voltage interval 34 lasts for the remaining 4 FROs or DCOs (25%). Accordingly, the predefined duty cycle is said to be 75%. In this regard, to modulate the bus symbol T_{S} to represent the binary “1,” a higher bus voltage V_{HIGH} is first asserted on the single-wire bus 28 for 75% of the duration of the bus symbol T_{S} and then a lower bus voltage V_{LOW} is asserted on the single-wire bus 28 for 25% of the duration of the bus symbol T_{S}. Notably, the bus symbol T_{S} can also be modulated to represent the binary “1” by configuring the predefined low-voltage interval 34 to last for the first 4 FROs or DCOs (25%) and the predefined high-voltage interval 32 to last for the remaining 12 FROs or DCOs (75%).

It should be appreciated from the discussion in FIGS. 2B and 2C that the bus symbol T_{S} can also be modulated based on other duty cycles. For example, to modulate the bus symbol T_{S} based on a 50% duty cycle, a higher bus voltage V_{HIGH} and a lower bus voltage V_{LOW} would each be asserted on the single-wire bus 28 for 50% duration of the bus symbol T_{S}.

Embodiments of the present disclosure are now discussed with reference to FIGS. 3 to 6. FIG. 3 is a schematic diagram of an exemplary single-wire bus circuit 36 that can be adapted according to various embodiments of the present disclosure to enable a Scan test despite that the single-wire bus circuit 36 only exposes a bus pin 38 for external access via a single-wire bus 40. In a non-limiting example, the single-wire bus circuit 36 can be functionally equivalent to any of the slave circuits 26(1)-26(M) in FIG. 2A. In this regard, the single-wire bus circuit 36 can communicate with a master circuit 42, such as the master circuit 24 in FIG. 2A, in multiple bus symbols T_{S} based on the full-duplex communications scheme described in APP510. Similar to the bus symbols T_{S} in FIG. 2A, each of the bus symbols T_{S} can also be pulse-width modulated to carry a binary “0” or a binary “1.”

The single-wire bus circuit 36 includes a communication circuit 44 that is under test. The single-wire bus circuit 36 further includes a driver circuit 46 to provide multiple test pins 48(1)-48(N) for enabling a test (e.g., Scan test) in the communication circuit 44. The test pins 48(1)-48(N) can be divided into a first subset of test pins 48(1)-48(L) and a second set of test pins 48(L+1)-48(N) (L<N). In a non-limiting example, the first subset of the test pins 48(1)-48(L) is used as input pins to provide test inputs to the communication circuit 44, and the second subset of test pins 48(L+1)-48(N) is used as output pins to receive test results from the communication circuit 44. In an embodiment, the driver circuit 46 includes a test driver circuit 50 configured to bridge the bus pin 38 with the test pins 48(1)-48(N).

The single-wire bus circuit 36 can be configured to operate in a test mode to conduct the test in the communication circuit 44 or in a communication mode to carry out normal communications with the master circuit 42. When operating in the communication mode, the communication circuit 44 is coupled to the bus pin 38 to communicate with the master circuit 42 based on the full-duplex bus communications scheme described in APP510. In the meantime, the test driver circuit 50 is decoupled from the bus pin 38.

When operating in the test mode, the test driver circuit 50 is coupled to the bus pin 38 and the communication circuit 44 is decoupled from the bus pin 38. Accordingly, the test driver circuit 50 receives one or more test input values 52 (e.g., SI and SE) from the master circuit 42 and transmits one or more test output values 54 (e.g., SO) to the master circuit 42.

In an embodiment, the master circuit 42 may be replaced by a test equipment 56 or configured to act as the test equipment 56 to conduct the test in the communication circuit 44 in the test mode. Regardless of how the test equipment 56 is provided, the test equipment 56 is configured to communicate with the test driver circuit 50 based on the full-duplex communications scheme described in APP510.

The test driver circuit 50 is configured to provide the test input values 52 to the communication circuit 44 via the first subset of the test pins 48(1)-48(L) to thereby cause the test to be performed in the communication circuit 44. During the test mode, the test driver circuit 50 also receives the test output values 54 resulting from the test performed in the communication circuit 44 via the second subset of the test pins 48(L+1)-48(N). In an embodiment, the test driver circuit 50 is configured to provide the test input values 52 to the communication circuit 44 and receive the test output values 54 from the communication circuit 44 concurrently.

By bridging the external bus pin 38 with the internal test pins 48(1)-48(N) using the driver circuit 46, it is possible to carry out a Scan test in the communication circuit 44 without adding additional external pins to the single-wire bus circuit 36. As a result, it is possible to test the communication circuit 44 thoroughly to ensure reliability of the single-wire bus circuit 36, without increasing complexity and footprint of the single-wire bus circuit 36.

To toggle the single-wire bus circuit 36 between the test mode and the communication mode, the driver circuit 46 also includes a switch circuit 58. The switch circuit 58 is coupled between the bus pin 38, the test driver circuit 50, and the communication circuit 44. The switch circuit 58 may be controlled to couple or decouple any of the test driver circuit 50 and the communication circuit 44 to or from the bus pin 38.

In an embodiment, the switch circuit 58 may be controlled by a driver controller 60. In a non-limiting example, the driver controller 60 can receive an explicit indication 62 via a test mode (TM) pin 64. The explicit indication 62 may be provided by asserting or de-asserting a voltage on the TM pin 64. For example, the voltage can be increased above a threshold (a.k.a. asserted) to indicate the test mode or decreased below the threshold (a.k.a., de-asserted) to indicate the communication mode, or vice versa.

The single-wire bus circuit 36 may automatically engage in the communication mode when the single-wire bus circuit 36 is powered up. In this regard, the explicit indication 62 will be automatically de-asserted each time the single-wire bus circuit 36 is power cycled or reset. In contrast, the explicit indication 62 has to be deliberately asserted to engage the single-wire bus circuit 36 in the test mode. In a non-limiting example, during the communication mode, the master circuit 42 can communicate a test initiation command CMD_{INIT} to the communication circuit 44 in a bus telegram(s) to instruct the communication circuit 44 to switch from the communication mode to the test mode. Accordingly, the communication circuit 44 can assert the explicit indication 62 to cause the test driver circuit 50 to enter the test mode.

In response to receiving the explicit indication 62 that indicates the test mode, the driver controller 60 controls the switch circuit 58 to couple the test driver circuit 50 to the bus pin 38 and decouple the communication circuit 44 from the bus pin 38. In contrast, in response to receiving the explicit indication 62 that indicates the communication mode, the driver controller 60 controls the switch circuit 58 to decouple the test driver circuit 50 from the bus pin 38 and couple the communication circuit 44 to the bus pin 38.

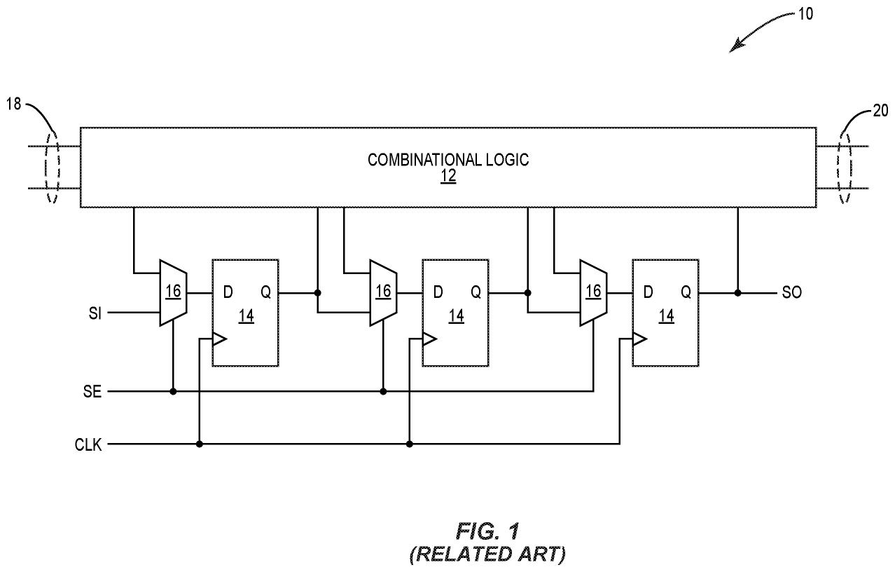

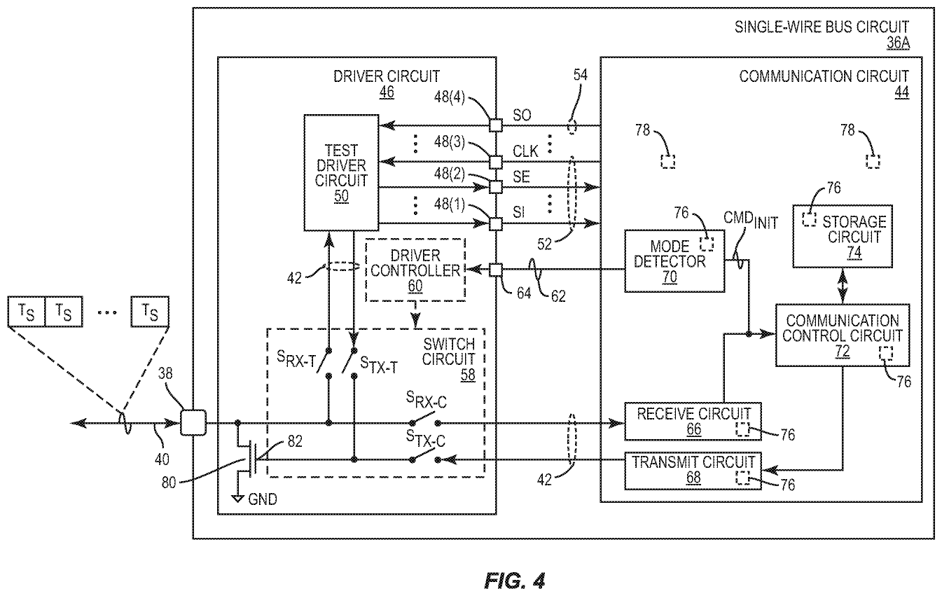

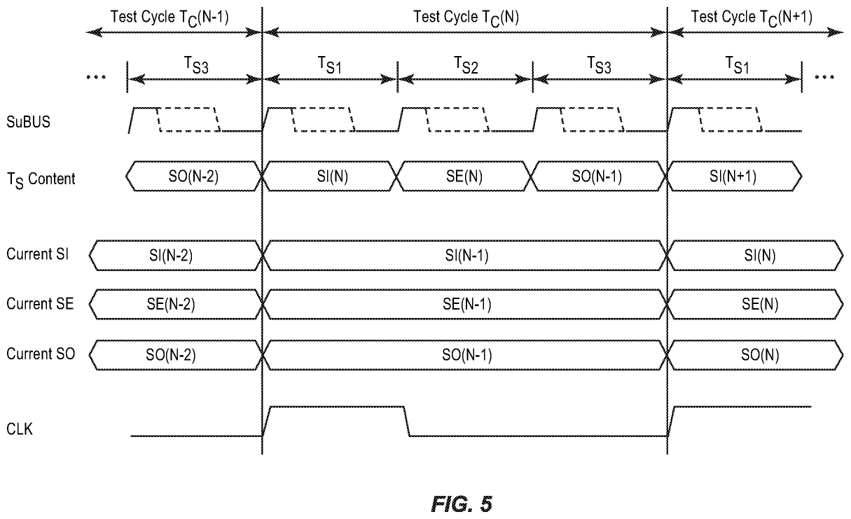

The single-wire bus circuit 36 can be adapted to support the Scan test, as described in FIG. 1, by configuring some or all of the test pins 48(1)-48(N) to function as the SI pin, the SE pin, the CLK pin, and the SO pin. In this regard, FIG. 4 is a schematic diagram of an exemplary single-wire bus circuit 36A, which is adapted from the single-wire bus circuit 36 of FIG. 3 according to an embodiment of the present disclosure to support the Scan test. Common elements between FIGS. 3 and 4 are shown therein with common element numbers and will not be re-described herein.

In this embodiment, the driver circuit 46 is configured to include the test pins 48(1)-48(4) from the test pins 48(1)-48(N) (N≥4) in FIG. 3. Specifically, the test pins 48(1)-48(3) are configured to function as an SI pin, an SE pin, and a CLK pin, respectively, and the test pin 48(4) is configured to function as an SO pin. In this regard, the test pins 48(1)-48(3) constitute the first subset of the test pins 48(1)-48(L) in FIG. 3, and the test pin 48(4) constitutes the second subset of the test pins 48(L+1)-48(N) in FIG. 3. Although the driver circuit 46 is shown to include only the test pins 48(1)-48(4), it should be appreciated that the driver circuit 46 can include additional spare test pins that are unused for the Scan test.

When operating in the test mode, the test driver circuit 50 provides an SI value (denoted as “SI”), an SE value (denoted as “SE”), and a CLK value (denoted as “CLK”) to the SI pin 48(1), the SE pin 48(2), and the CLK pin 48(3), respectively, to thereby cause the Scan test to be performed in the communication circuit 44. The test driver circuit 50 also receives an SO value (denoted as “SO”), which indicates a result of the Scan test performed in the communication circuit 44, via the SO pin 48(4). In this embodiment, each of the SI value, the SE value, and the SO value is pulse-width modulated to represent a binary “0” or a binary “1,” as previously illustrated in FIGS. 2B and 2C, respectively.

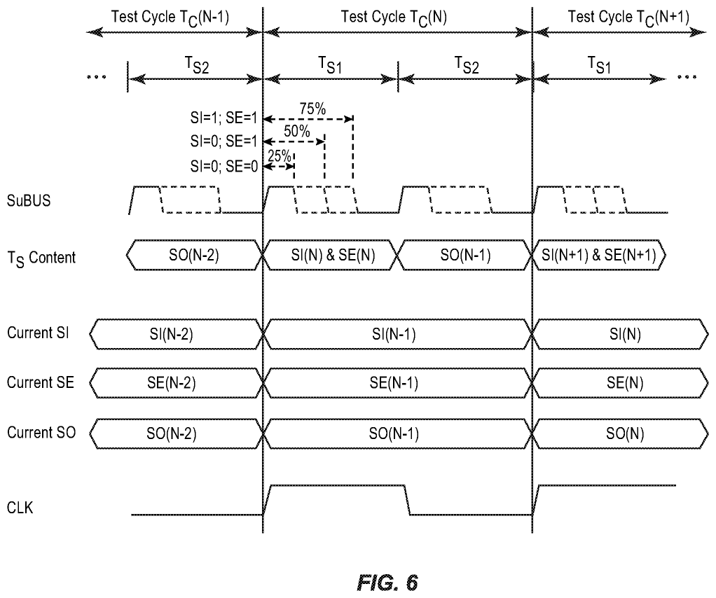

According to the previous discussion in FIG. 4, the test driver circuit 50 is configured to operate as a bridge between the bus pin 38 and the test pins 48(1)-48(4). In one aspect, the test driver circuit 50 needs to communicate the SI value, the SE value, the CLK value, and the SO value with the communication circuit 44 in parallel via the test pins 48(1)-48(4). In another aspect, the test driver circuit 50 also needs to communicate the SI value, the SE value, and the SO value with the test equipment 56 in the bus symbols T_{S}, which are only conveyed in serial over the single-wire bus 40. In this regard, the test driver circuit 50 would need to provide a serial-to-parallel conversion between the bus pin 38 and the test pins 48(1)-48(4). This may be done by dividing and grouping the bus symbols T_{S} into multiple test cycles, as discussed in detail in FIGS. 5 and 6 below.

FIG. 5 of is a graphic diagram providing an exemplary illustration of the Scan test performed by the single-wire bus circuit 36A of FIG. 4 in accordance with one embodiment of the present disclosure. Common elements between FIGS. 4 and 5 are shown therein with common element numbers and will not be re-described herein.

FIG. 5 illustrates three consecutive test cycles T_{C}(N−1), T_{C}(N), T_{C}(N+1) as a non-limiting example. Among them, the test cycle T_{C}(N−1) is referred to as “an immediately preceding test cycle” to the test cycle T_{C}(N), and the test cycle T_{C}(N+1) is referred to as “an immediately succeeding test cycle” to the test cycle T_{C}(N). In this embodiment, each of the test cycles T_{C}(N−1), T_{C}(N), T_{C}(N+1) includes a first bus symbol T_{S1}, a second bus symbol T_{S2}, and a third bus symbol T_{S3}, which are consecutive bus symbols among the test symbols T_{S} communicated over the single-wire bus 40.

In a non-limiting example, in each of the test cycles T_{C}(N−1), T_{C}(N), T_{C}(N+1), the test driver circuit 50 is configured to receive the SI value in the first bus symbol T_{S1}, receive the SE value in the second bus symbol T_{S2}, and transmit the SO value in the third bus symbol T_{S3}. Understandably, the first bus symbol T_{S1}, the second bus symbol T_{S2}, and the third bus symbol TSs are each pulse-width modulated to represent the binary “0” or the binary “1” based on previous examples shown in FIGS. 2B and 2C, respectively. The test driver circuit 50 is further configured to derive the CLK value on the third bus symbol T_{S3}, which is the last bus symbol in each of the test cycles T_{C}(N−1), T_{C}(N), T_{C}(N+1). It should be appreciated that the SI value, the SE value, and the SO value can be communicated in any order in each of the test cycles T_{C}(N−1), T_{C}(N), T_{C}(N+1), without changing the operating principle described herein.

During the test cycle T_{C}(N), the SI value (denoted as “SI(N−1)”), the SE value (denoted as “SE(N−1)”), and the SO value (denoted as “SO(N−1)”) available on the SI pin 48(1), the SE pin 48(2), and the SO pin 48(4) were actually set in the immediately preceding test cycle T_{C}(N−1). In this regard, the SO value transmitted to the test equipment 56 in the third bus symbol T_{S3} is the SO value SO(N−1) generated in the immediately preceding test cycle T_{C}(N−1).

During the test cycle T_{C}(N), the test driver circuit 50 receives the SI value (denoted as “SI(N)”) in the first bus symbol T_{S1} and the SE value (denoted as “SE(N)”) in the second bus symbol T_{S2}. Notably, the SI value SI(N) and the SE value SE(N) received during the test cycle T_{C}(N) are to be applied to the SI pin 48(1) and the SE pin 48(2) in the immediately succeeding test cycle T_{C}(N+1). Similarly, the SO value (denoted as “SO(N)”) generated during the test cycle T_{C}(N) is only accessible on the SO pin 48(4) in the immediately succeeding test cycle T_{C}(N+1).

From the example above, it is apparent that there exists one test cycle delay between the bus pin 38 and the test pins 48(1)-48(4). Understandably, the delay is a result of the serial-to-parallel conversion performed by the test driver circuit 50.

FIG. 6 of is a graphic diagram providing an exemplary illustration of the Scan test performed by the single-wire bus circuit 36A of FIG. 4 in accordance with another embodiment of the present disclosure. Common elements between FIGS. 4 and 6 are shown therein with common element numbers and will not be re-described herein.

FIG. 6 illustrates three consecutive test cycles T_{C}(N−1), T_{C}(N), and T_{C}(N+1) as a non-limiting example. Among them, the test cycle T_{C}(N−1) is referred to as “an immediately preceding test cycle” to the test cycle T_{C}(N), and the test cycle T_{C}(N+1) is referred to as “an immediately succeeding test cycle” to the test cycle T_{C}(N). In this embodiment, each of the test cycles T_{C}(N−1), T_{C}(N), T_{C}(N+1) includes a first bus symbol T_{S1} and a second bus symbol T_{S2}, which are consecutive bus symbols among the test symbols T_{S} communicated over the single-wire bus 40.

In a non-limiting example, in each of the test cycles T_{C}(N−1), T_{C}(N), T_{C}(N+1), the test driver circuit 50 is configured to receive the SI value and the SE value in the first bus symbol T_{S1} and transmit the SO value in the second bus symbol T_{S2}. Understandably, the first bus symbol T_{S1} and the second bus symbol T_{S2} are each pulse-width modulated to represent the binary “0” or the binary “1” based on previous examples shown in FIGS. 2B and 2C, respectively. The test driver circuit 50 is further configured to derive the CLK value on the second bus symbol T_{S2}, which is the last bus symbol in each of the test cycles T_{C}(N−1), T_{C}(N), T_{C}(N+1).

In a non-limiting example, the SI value and the SE value can be represented in the first bus symbol T_{S1} based on different PWM duty cycles, as shown in the table below.

| PWM Duty Cycle | SI | SE |
|---|---|---|
| 25% | “0” | “0” |
| 50% | “0” | “1” |
| 75% | “1” | “1” |

During the test cycle T_{C}(N), the SI value (denoted as “SI(N−1)”), the SE value (denoted as “SE(N−1)”), and the SO value (denoted as “SO(N−1)”) available on the SI pin 48(1), the SE pin 48(2), and the SO pin 48(4) were actually set in the immediately preceding test cycle T_{C}(N−1). In this regard, the SO value transmitted to the test equipment 56 in the second bus symbol T_{S2} is the SO value SO(N−1) generated in the immediately preceding test cycle T_{C}(N−1).

During the test cycle T_{C}(N), the test driver circuit 50 receives the SI value (denoted as “SI(N)”) and the SE value (denoted as “SE(N)”) in the first bus symbol T_{S1}. Notably, the SI value SI(N) and the SE value SE(N) received during the test cycle T_{C}(N) are to be applied to the SI pin 48(1) and the SE pin 48(2) in the immediately succeeding test cycle T_{C}(N+1). Similarly, the SO value (denoted as “SO(N)”) generated during the test cycle T_{C}(N) is only accessible on the SO pin 48(4) in the immediately succeeding test cycle T_{C}(N+1).

With reference back to FIG. 4, the communication circuit 44 includes a receive circuit 66, a transmit circuit 68, a mode detector 70, a communication control circuit 72, and a storage circuit 74. Each of the receive circuit 66, the transmit circuit 68, the mode detector 70, the communication control circuit 72, and the storage circuit 74 may have an embedded register circuit 76 (e.g., flip flop circuit) that can be configured to perform the Scan test. In addition to the embedded register circuit 76, the communication circuit 44 may also include one or more redundant register circuits 78 that may be utilized for the Scan test as well.

The driver circuit 46 includes a current sink 80, which can be an N-type transistor for example. The current sink 80 is coupled between the bus pin 38 and a ground (GND). The switch circuit 58 includes a communication transmit switch S_{TX-C}, a communication receive switch S_{RX-C}, a test transmit switch S_{TX-T}, and a test receive switch S_{RX-T}. The communication receive switch S_{RX-C} is coupled between the receive circuit 66 and the bus pin 38 and the communication transmit switch S_{TX-C} is coupled between the transmit circuit 68 and an input 82 (e.g., a gate electrode of the N-type transistor) of the current sink. The test receive switch S_{RX-T} is coupled between the test driver circuit 50 and the bus pin 38 and the test transmit switch S_{TX-T} is coupled between the test driver circuit 50 and the input 82 of the current sink.

When operating in the communication mode, the driver controller 60 will open both the test transmit switch S_{TX-T} and the test receive switch S_{RX-T} to decouple the test driver circuit 50 from the bus pin 38. The driver controller 60 closes the communication receive switch S_{RX-C} and opens the communication transmit switch S_{TX-C} such that the receive circuit 66 can receive the data write telegrams from the master circuit 42. The driver controller 60 opens the communication receive switch S_{RX-C} and closes the communication transmit switch S_{TX-C} such that the transmit circuit 68 can transmit the data read symbols to the master circuit 42.

In an embodiment, the receive circuit 66 can receive the test initiation command CMD_{INIT} from one of the data write telegrams and provide the test initiation command CMD_{INIT} to the mode detector 70. Accordingly, the mode detector 70 can assert the TM pin 64 in response to receiving the test initiation command CMD_{INIT} from the receive circuit 66.

When operating in the test mode, the driver controller 60 will open both the communication transmit switch S_{TX-C} and the communication receive switch S_{RX-C} to decouple the communication circuit 44 from the bus pin 38. The driver controller 60 closes the test receive switch S_{RX-T} and opens the test transmit switch S_{TX-T} to allow the test driver circuit 50 to receive the SI value and the SE value from the test equipment 56 in the data write telegrams. The driver controller 60 opens the test receive switch S_{RX-T} and closes the test transmit switch S_{TX-T} to allow the test driver circuit 50 to transmit the SO value to the test equipment 56 in the data read symbols.

The single-wire bus circuit 36A is configured to transmit the data read symbols via the current sink 80. As described in detail in APP510, the master circuit 42 is configured to always modulate each of the data read symbols to the binary “1” by asserting the higher bus voltage V_{HIGH} and the lower bus voltage V_{LOW} on the single-wire bus 40 based on, for example, the 75% duty cycle. In this regard, the single-wire bus circuit 36A does not need to do anything if the single-wire bus circuit 36A intends to transmit the binary “1” in any of the data read symbols. As a result, the driver circuit 46 can deactivate the current sink 80.

However, the single-wire bus circuit 36A would need to transmit the binary “0” in any of the data read symbols, the single-wire bus circuit 36A would need to pull the higher bus voltage V_{HIGH} down earlier in accordance with the 25% duty cycle. As such, the driver circuit 46 needs to activate the current sink 80 to thereby reduce the higher bus voltage V_{HIGH} on the single-wire bus 40.

In this regard, when operating in the test mode, the test driver circuit 50 will determine whether the SO value represents a binary “0” or a binary “1” in each of the test cycles T_{C}(N−1), T_{C}(N), T_{C}(N+1). The test driver circuit 50 will activate the current sink 80 in response to determining that the SO value equals the binary “0” and deactivate the current sink 80 in response to determining that the SO value equals the binary “1.” In an embodiment, the test driver circuit 50 can activate the current sink 80 immediately upon determining that the SO value equals the binary “0.”

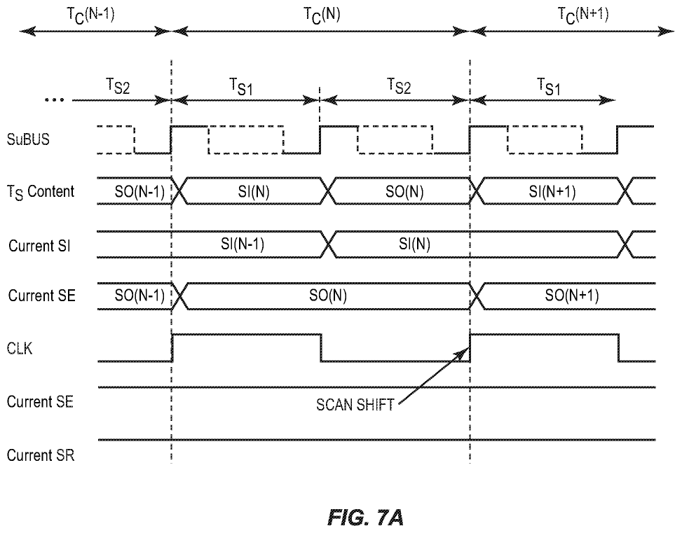

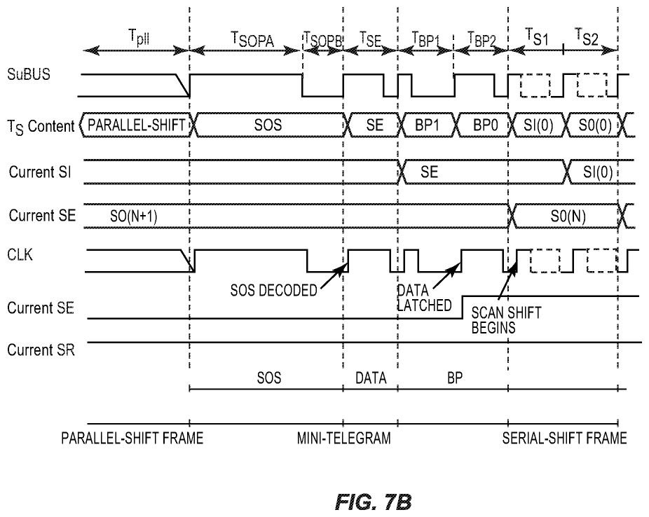

FIG. 7A of is a graphic diagram providing an exemplary illustration of the Scan test performed by the single-wire bus circuit 36A of FIG. 4 in accordance with another embodiment of the present disclosure. Common elements between FIGS. 4 and 7 are shown therein with common element numbers and will not be re-described herein.

FIG. 7A illustrates three consecutive test cycles T_{C}(N−1), T_{C}(N), and T_{C}(N+1) as a non-limiting example. Among them, the test cycle T_{C}(N−1) is referred to as “an immediately preceding test cycle” to the test cycle T_{C}(N), and the test cycle T_{C}(N+1) is referred to as “an immediately succeeding test cycle” to the test cycle T_{C}(N). In this embodiment, each of the test cycles T_{C}(N−1), T_{C}(N), T_{C}(N+1) includes a first bus symbol T_{S1} and a second bus symbol T_{S2}, which are consecutive bus symbols among the test symbols T_{S} communicated over the single-wire bus 40.

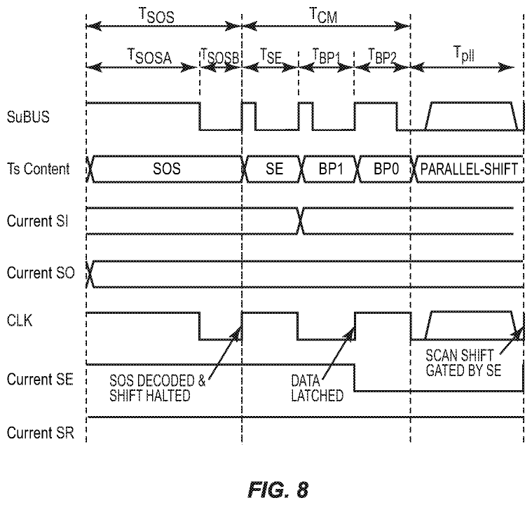

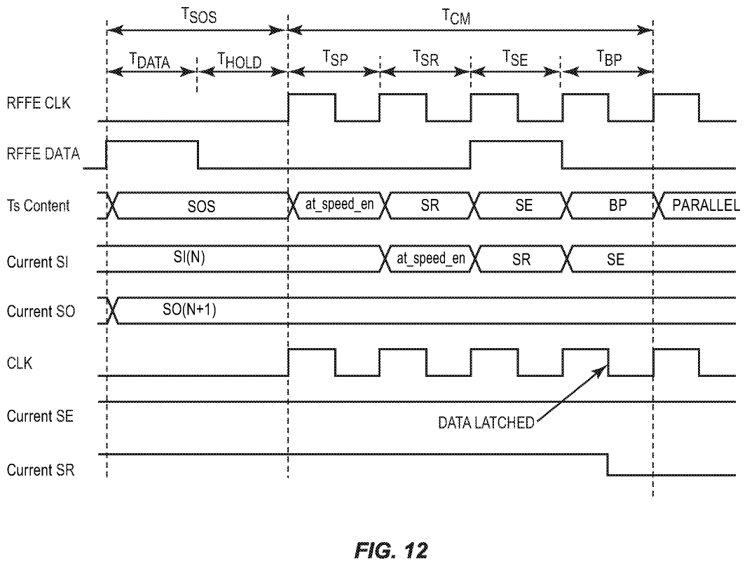

In a non-limiting example, in each of the test cycles T_{C}(N−1), T_{C}(N), T_{C}(N+1), the test driver circuit 50 is configured to receive the SI value in the first bus symbol T_{S1} and transmit the SO value in the second bus symbol T_{S2}. Note that, in these embodiments, an SE value is not included during any of the test cycles test cycles T_{C}(N−1), T_{C}(N), T_{C}(N+1). In fact, in these embodiments, no other value other than the SI value and the SO value are provided during each of the test cycles T_{C}(N−1), T_{C}(N), T_{C}(N+1). This is because, prior to any of the test cycles with the SI value and the SO value, a mini-telegram is provided. The mini-telegram includes a start of scan (SOS) sequence and a series of bus values, such as the SE value. This is advantageous because, in some embodiments, certain bus values (such as the SE value) are the same for all of the register circuits 14. Examples of the SOS sequence and the common bus values are discussed with respect to FIG. 8-FIG. 10, FIG. 12. By providing the common bus values at the beginning during the mini-telegram, the common bus values do not have to be repeated during each serial-shift frame when the SI values and the SO values are being transmitted.

Understandably, the first bus symbol T_{S1} and the second bus symbol T_{S2} are each pulse-width modulated to represent the binary “0” or the binary “1” based on previous examples shown in FIGS. 2B and 2C, respectively. The test driver circuit 50 is further configured to derive the clock signal CLK on the clock pin 48(3) is derived directly from the pulses on the single-wire bus 40. As such, During the first bus symbol T_{S1}, the current SI value is provided on the single wire bus 40. The SI value is captured during the second bus symbol T_{S2}. The communication circuit transmits the SO value during the first bus symbol T_{S1} and second bus symbol T_{S2}. The SO value is captured during the second bus symbol T_{S2}.

In a non-limiting example, the SI value and the SO value can be represented based on different PWM duty cycles, as shown in the table below.

| PWM Duty Cycle | SI | SO |
|---|---|---|
| 25% | “0” | “0” |
| 75% | “1” | “1” |

During the test cycle T_{C}(N), the SI value (denoted as “SI(N−1)”) available on the SI pin 48(1) during the first symbol period T_{S1} is set in the immediately preceding test cycle T_{C}(N−1). During the first bus symbol T_{S1} of the test cycle T_{C}(N), the test driver circuit 50 receives the SI value (denoted as “SI(N)”) in the first bus symbol T_{S1}. Notably, the SI value SI(N) received during the test cycle T_{C}(N) are to be applied to the SI pin 48(1) in the second bus symbol T_{S2} of the test cycle T_{C}(N) and during the first bus symbol T_{S2} of the immediately succeeding test cycle T_{C}(N+1). Similarly, the SO value (denoted as “SO(N)”) generated during the test cycle T_{C}(N) is accessible on the SO pin 48(4) in the test cycle T_{C}(N+1). The SO value (denoted “SO(N)” on the SO pin 48(1) is provided during the current test cycle T_{C}(N). Note that the SE value and the SR value are constantly held at the same value (e.g., a high voltage value in FIG. 7A) because the SE value and the SR value were set as a result of the mini-telegram, as explained in further detail below.

With reference back to FIG. 4, the communication circuit 44 includes a receive circuit 66, a transmit circuit 68, a mode detector 70, a communication control circuit 72, and a storage circuit 74. Each of the receive circuit 66, the transmit circuit 68, the mode detector 70, the communication control circuit 72, and the storage circuit 74 may have an embedded register circuit 76 (e.g., flip flop circuit) that can be configured to perform the Scan test. In addition to the embedded register circuit 76, the communication circuit 44 may also include one or more redundant register circuits 78 that may be utilized for the Scan test as well.

The driver circuit 46 includes a current sink 80, which can be an N-type transistor for example. The current sink 80 is coupled between the bus pin 38 and a ground (GND). The switch circuit 58 includes a communication transmit switch S_{TX-C}, a communication receive switch S_{RX-C}, a test transmit switch S_{TX-T}, and a test receive switch S_{RX-T}. The communication receive switch S_{RX-C} is coupled between the receive circuit 66 and the bus pin 38 and the communication transmit switch S_{TX-C} is coupled between the transmit circuit 68 and an input 82 (e.g., a gate electrode of the N-type transistor) of the current sink. The test receive switch S_{RX-T} is coupled between the test driver circuit 50 and the bus pin 38 and the test transmit switch S_{TX-T} is coupled between the test driver circuit 50 and the input 82 of the current sink.

When operating in the communication mode, the driver controller 60 will open both the test transmit switch S_{TX-T} and the test receive switch S_{RX-T} to decouple the test driver circuit 50 from the bus pin 38. The driver controller 60 closes the communication receive switch S_{RX-C} and opens the communication transmit switch S_{TX-C} such that the receive circuit 66 can receive the data write telegrams from the master circuit 42. The driver controller 60 opens the communication receive switch S_{RX-C} and closes the communication transmit switch S_{TX-C} such that the transmit circuit 68 can transmit the data read symbols to the master circuit 42.

In an embodiment, the receive circuit 66 can receive the test initiation command CMD_{INIT} from one of the data write telegrams and provide the test initiation command CMD_{INIT} to the mode detector 70. Accordingly, the mode detector 70 can assert the TM pin 64 in response to receiving the test initiation command CMD_{INIT} from the receive circuit 66.

When operating in the test mode, the driver controller 60 will open both the communication transmit switch S_{TX-C} and the communication receive switch S_{RX-C} to decouple the communication circuit 44 from the bus pin 38. The driver controller 60 closes the test receive switch S_{RX-T} and opens the test transmit switch S_{TX-T} to allow the test driver circuit 50 to receive the SI value and the SE value from the test equipment 56 in the data write telegrams. The driver controller 60 opens the test receive switch S_{RX-T} and closes the test transmit switch S_{TX-T} to allow the test driver circuit 50 to transmit the SO value to the test equipment 56 in the data read symbols.

The single-wire bus circuit 36A is configured to transmit the data read symbols via the current sink 80. As described in detail in APP510, the master circuit 42 is configured to always modulate each of the data read symbols to the binary “1” by asserting the higher bus voltage V_{HIGH} and the lower bus voltage V_{LOW} on the single-wire bus 40 based on, for example, the 75% duty cycle. In this regard, the single-wire bus circuit 36A does not need to do anything if the single-wire bus circuit 36A intends to transmit the binary “1” in any of the data read symbols. As a result, the driver circuit 46 can deactivate the current sink 80.

However, the single-wire bus circuit 36A would need to transmit the binary “0” in any of the data read symbols, the single-wire bus circuit 36A would need to pull the higher bus voltage V_{HIGH} down earlier in accordance with the 25% duty cycle. As such, the driver circuit 46 needs to activate the current sink 80 to thereby reduce the higher bus voltage V_{HIGH} on the single-wire bus 40.

In this regard, when operating in the test mode, the test driver circuit 50 will determine whether the SO value represents a binary “0” or a binary “1” in each of the test cycles T_{C}(N−1), T_{C}(N), T_{C}(N+1). The test driver circuit 50 will activate the current sink 80 in response to determining that the SO value equals the binary “0” and deactivate the current sink 80 in response to determining that the SO value equals the binary “1.” In an embodiment, the test driver circuit 50 can activate the current sink 80 immediately upon determining that the SO value equals the binary “0.” Note that the test cycles are repeated for each of the register circuit 14 in the communication circuit 72 that is under test.

FIG. 7B is a graphic diagram providing an exemplary illustration of the Scan test performed by the single-wire bus circuit 36A of FIG. 4 in accordance with another embodiment of the present disclosure. Common elements between FIGS. 4 and 8 are shown therein with common element numbers and will not be re-described herein.

The Scan test shows a mini-telegram transmitted at the before the serial scan shift shown in FIG. 7A but before the beginning of the Scan test, as shown in FIG. 8. The mini-telegram is used to indicate that a parallel shift processed by the combinational logic has ended so that the serial shift (See FIG. 7A) can begin. The mini-telegram has an SOS sequence (labeled SOS) at the beginning that is transmitted during an SOP time period T_{SOP} and common bus values (e.g., SE value, BP1 value, BP2 value). The SOS sequence is a sequence that clearly indicates a beginning of a serial shift of the Scan test and is clearly distinguishable from other pulse patterns transmitted on the bus 40. In this embodiment, a high voltage value V_{HIGH} is transmitted during a time period T_{SOPA}. The time period T_{SOSA} is greater or equal to 1.5 T_{S} but less than or equal to 2.5 T_{S}. Immediately following the time period T_{SOPA} is the time period T_{SOPB}. The time period T_{SOSB} is less than or equal to 0.25 T_{S}. During the time period T_{SOSB}, a low voltage value V_{LOW} is transmitted. This pattern is distinguishable from any of the other bus patterns on the bus 40. Accordingly, whenever the SOS sequence is present after the beginning of the Scan test (See FIG. 8), the driver circuit 46 is configured to begin the serial scan shift.

Immediately after the time period T_{SOP}, a common bus value time period T_{CM} is generated on the bus 40. The common bus value time period T_{CP} includes a bus symbol T_{SE}, followed by a bus symbol TS_{BP1}, followed then by a bus symbol TS_{BP2}. During the bus symbol T_{SE}, the SE value is transmitted. The SE value is common to all of the register circuits 14. Thus, each set of test inputs that are transmitted to the communication circuit 44 includes the SE value. Each set of test inputs during the serial shift frame (See FIG. 7A) includes a different one of the SI values (e.g., SI(N−1), SI(N), SI(N+1) and the same SE value. In this embodiment, the SE value is a value of 1 indicating that the serial scan shift is to begin.

During the bus symbol T_{BP1}, the BP1 value is transmitted. The BP1 value is common to all of the register circuits 14. Thus, each set of test inputs that are transmitted to the communication circuit 44 includes the BP1 value. Each set of test inputs during the serial shift frame (See FIG. 7A) includes a different one of the SI values (e.g., SI(N−1), SI(N), SI(N+1) and the same BP1 value.

During the bus symbol T_{BP2}, the BP2 value is transmitted. The BP2 value is common to all of the register circuits 14. Thus, each set of test inputs that are transmitted to the communication circuit 44 includes the BP2 value. Each set of test inputs during the serial shift frame (See FIG. 7A) includes a different one of the SI values (e.g., SI(N−1), SI(N), SI(N+1) and the same BP2 value. In this embodiment, the BP1 value is a 1 and the BP2 value is a 0. The SE value, the BP1 value, and the BP2 value are latched on the last positive edge of the clock signal CLK. In this example, the clock signal CLK is set to mimic the SuBus signal as events occur in response to the positive edges of the clock signal CLK. In other embodiments, each positive edge of the SuBus signal results in alternating positive and negative edges in the clock signal CLK.

FIG. 8 is a graphic diagram providing an exemplary illustration of the Scan test performed by the single-wire bus circuit 36A of FIG. 4 in accordance with another embodiment of the present disclosure. Common elements between FIGS. 4 and 8 are shown therein with common element numbers and will not be re-described herein.

The Scan test shows a mini-telegram transmitted at the beginning of the Scan test. The mini-telegram occurs before the parallel shift during the time period Tpll shown in FIG. 7B. The mini-telegram has an SOS sequence (labeled SOS) at the beginning that is transmitted during an SOS time period T_{SOS} and common bus values (e.g., SE value, BP1 value, BP2 value). The SOS sequence is a sequence that clearly indicates a beginning of a Scan test and is clearly distinguishable from other pulse patterns transmitted on the bus 40. In this embodiment, a high voltage value V_{HIGH} is transmitted during a time period T_{SOSA}. The time period T_{SOSA} is greater or equal to 1.5 T_{S} but less than or equal to 2.5 T_{S}. Immediately following the time period T_{SOSA} is the time period T_{SOSB}. The time period T_{SOSB} is less than or equal to 0.25 T_{S}. During the time period T_{SOSB}, a low voltage value V_{LOW} is transmitted. This pattern is distinguishable from any of the other bus patterns on the bus 40. Accordingly, whenever the SOS sequence is present, the driver circuit 46 is configured to begin a new Scan test.

Immediately after the time period T_{SOS}, a common bus value time period T_{CM} is generated on the bus 40. The common bus value time period T_{CM} includes a bus symbol T_{SE}, followed by a bus symbol TS_{BP1}, followed then by a bus symbol TS_{BP2}. During the bus symbol T_{SE}, the SE value is transmitted. The SE value is common to all of the register circuits 14. Thus, each set of test inputs that are transmitted to the communication circuit 44 includes the SE value. Each set of test inputs during the serial shift frame (See FIG. 7A) includes a different one of the SI values (e.g., SI(N−1), SI(N), SI(N+1) and the same SE value. In this embodiment, the SE value is at 0 to indicate that the parallel shift is about to being during the time period Tpll.

During the bus symbol T_{BP1}, the BP1 value is transmitted. The BP1 value is common to all of the register circuits 14. Thus, each set of test inputs that are transmitted to the communication circuit 44 includes the BP1 value. Each set of test inputs during the serial shift frame (See FIG. 7A) includes a different one of the SI values (e.g., SI(N−1), SI(N), SI(N+1) and the same BP1 value. The BP1 value and BP0 value are intended to be fixed symbols, common to every SuBUS Mini-Telegram. In this embodiment, the BP1 value is 0 and the BP0 value is a 1. The same BP1 value and the same, though other PWM/1-wire telegrams could choose a different configuration as required (00, 10, 11, 5.5, etc.). In a 2-wire interface (RFFE), the BP may just be a single bit.

During the bus symbol T_{BP2}, the BP2 value is transmitted. The BP2 value is common to all of the register circuits 14. Thus, each set of test inputs that are transmitted to the communication circuit 44 includes the BP2 value. Each set of test inputs during the serial shift frame (See FIG. 7A) includes a different one of the SI values (e.g., SI(N−1), SI(N), SI(N+1) and the same BP2 value.

In this embodiment, each edge (both positive and negative edges) of the clock signal CLK is triggered by a positive edge of the bus signal SuBus. Notice how the Mini-Telegram latch clock edge is dependent on the number of bits in a telegram. This is relevant if there are an even number of Mini-Telegram bits, where SE value should be latched on negative CLK edge rather than positive edge.

During the time period Toll, a parallel shift frame occurs where the previous SI values are entered into and processed by the combinational logic. After the time period Tpll, the second SOS is transmitted, as discussed in FIG. 7B. Once the second SOS and common bus values are transmitted as discussed in FIG. 7B, the serial shift occurs where the SI values and the SO values are provided as discussed in FIG. 7A.

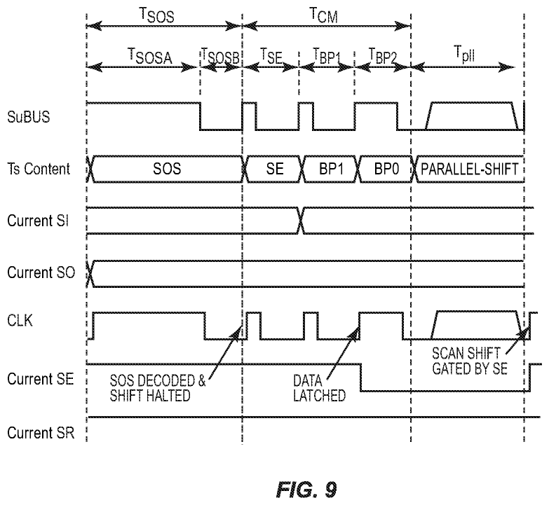

FIG. 9 is a graphic diagram providing an exemplary illustration of the Scan test performed by the single-wire bus circuit 36A of FIG. 4 in accordance with another embodiment of the present disclosure. Common elements between FIGS. 4 and 9 are shown therein with common element numbers and will not be re-described herein. The graphic diagram in FIG. 9 is the same as the graphic diagram in FIG. 8, except for the operation of the clock signal CLK.

In this embodiment, the test driver circuit 50 the clock signal CLK mimics the bus signal SuBus where events are triggered by the positive edges of the clock signal CLK. Thus, the duty cycle of the bus signal SuBus does not affect the timing of events since the positive edges are what is used to trigger the events. There is a delay between the bus signal SuBus and the clock signal CLK due to propagation delays. In other embodiments, an on-chip oscillator 90 is used to generate the clock signal CLK instead of edges of the pulses on the single-wire bus SuBUS as in FIG. 8. In some embodiments, the on-chip oscillator 90 is the same oscillator used to demodulate the pulses on the single-wire bus SuBUS. In some embodiments, this would halve the period of the clock signal SCLK compared to clock signal CLK in FIG. 8 and provide a consistent edge to latch data (positive edge). In some embodiments, utilizing the on-chip oscillator 90 to generate the clock signal CLK scheme delays the clock signal SCLK due to small desynchronization between the pulses on the bus SuBUS and the clock signal CLK generated by the on-chip oscillator 90.

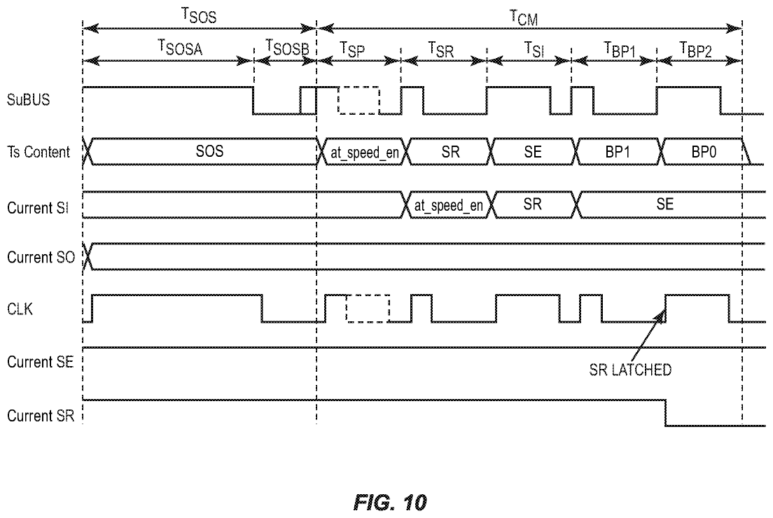

FIG. 10 is a graphic diagram providing an exemplary illustration of the Scan test performed by the single-wire bus circuit 36A of FIG. 4 in accordance with another embodiment of the present disclosure. Common elements between FIGS. 4 and 10 are shown therein with common element numbers and will not be re-described herein. The graphic diagram in FIG. 10 is the same as the graphic diagram in FIG. 9, except for the that the time period T_{CM} with the common bus values includes additional common bus values.

The time period T_{CM} begins with a bus symbol T_{SP}. During the bus symbol T_{SP}, an at_speed_en common bus value is provided on the bus SuBUS. The at_speed_en common bus value enables an ‘at-speed test-mode’, where during parallel-shift clock signal is directly driven by the on-chip oscillator 90 for a pre-defined number of clock cycles.

The at_speed_en common bus value is provided with each set of test inputs to each of the register circuits 16.

The bus symbol T_{SP} is followed by the bus symbol T_{SR}. During the bus symbol T_{SR}, the SR value is provided on the bus SuBUS. Furthermore, during the bus symbol T_{SR}, the at_speed_en common bus value is provided on the pin 48(1) typically used to carry the SI value. The SR value is provided with each set of test inputs to each of the register circuits 16.

The bus symbol T_{SR} is followed by the bus symbol T_{SE}. During the bus symbol T_{SE}, the SE value is provided on the bus SuBUS. Furthermore, during the bus symbol T_{SE}, the SR value is provided on the pin 48(1) typically used to carry the SI value. The SE value is provided with each set of test inputs to each of the register circuits 16.

The bus symbol T_{SE} is followed by the bus symbol T_{BP1}. During the bus symbol T_{BP1}, the BP1 value is provided on the bus SuBUS. Furthermore, during the bus symbol T_{BP1}, the SE value is provided on the pin 48(1) typically used to carry the SI value. The SE value is provided with each set of test inputs to each of the register circuits 16.

The bus symbol T_{BP1} is followed by the bus symbol T_{BP2}. During the bus symbol T_{BP2}, the BP2 value is provided on the bus SuBUS. Furthermore, in response to the positive clock edge of the clock signal CLK during the bus symbol T_{BP2}, the SR value is latched from the test driver circuit 50 to the communication circuit 44.

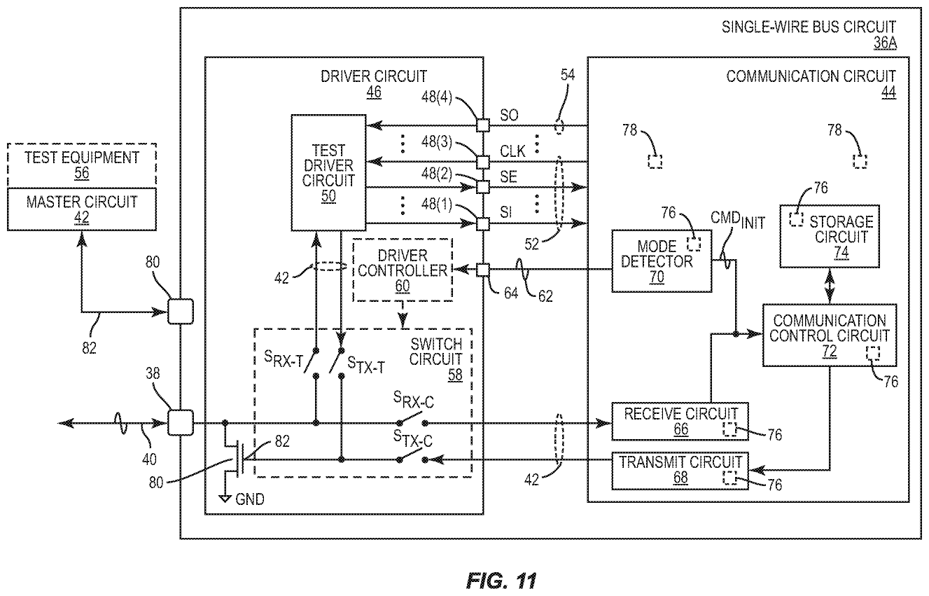

FIG. 11 is a schematic diagram of an exemplary bus circuit 36B, in accordance with some embodiments.

The bus circuit 36B is the same as the single-wire bus circuit 36A in FIG. 4, except that the bus circuit 36B has an additional bus wire 82 that connects to a bus pin 80 in the bus circuit 36B. Common elements between FIGS. 4 and 1 are shown therein with common element numbers and will not be re-described herein.

In this embodiment, a clock signal RFFE CLK is transmitted from the master circuit 42 and/or the test equipment 56. The timing on the bus circuit 36 is timed in accordance with the clock pulses of the clock signal RFFE CLK. In some embodiments, the test driver circuit 50 is simply configured to pass the clock signal RFFE CLK as the clock signal CLK on the test pin 48(3). In other embodiments, the oscillator 90 is configured to generate the clock signal CLK such that the clock signal CLK is synchronized in accordance with the clock signal RFFE CLK that is received by the bus pin 80. The serial shift is performed by the bus circuit 36B in the same manner shown in FIG. 7A. A mini-telegram is transmitted at the beginning of the Scan test to indicate that the mini-telegram has started.

FIG. 12 is a graphic diagram providing an exemplary illustration of the Scan test performed by the bus circuit 36B of FIG. 11 in accordance with another embodiment of the present disclosure. Common elements between FIGS. 11 and 12 are shown therein with common element numbers and will not be re-described herein.

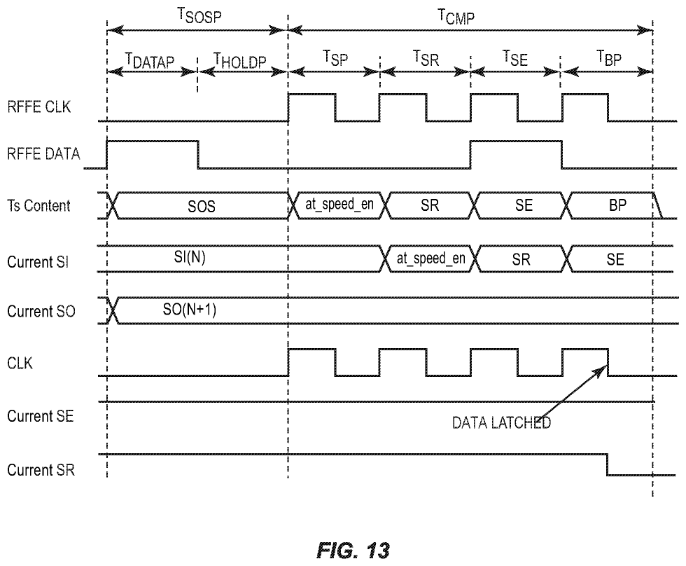

The Scan test shows a mini-telegram transmitted at the beginning of the Scan test. The mini-telegram has an SOS sequence (labeled SOS) at the beginning that is transmitted during an SOS time period T_{SOS} and common bus values (e.g., at en_speed_en, SR value, SE value, BP1 value, BP2 value) along the data line RFFE DATA. The SOS sequence is a sequence that clearly indicates a beginning of a Scan test and is clearly distinguishable from other pulse patterns transmitted on the bus 40. In this embodiment, the clock signal RFFE CLK on bus line 82 is held low throughout the entirety of the SOS time period T_{SOS}. Furthermore, a high voltage value V_{HIGH} is transmitted during a time period TDATA. The time period TDATA is equal to half the time period T_{SOS}. Immediately following the time period TDATA is the time period T_{HOLD}. The time period T_{SOSB} is equal to half the time period T_{SOS}. During the time period T_{HOLD}, a low voltage value V_{LOW} is transmitted on the bus line 40. This pattern is distinguishable from any of the other bus patterns on the bus line 40 and the bus line 82. In particular, in no other circumstance than after the parallel shift (See FIG. 13) is the bus line 82 held low while the bus line 40 held high. As such, this is a clear signal that a Scan test is beginning. Accordingly, whenever the SOS sequence is present at the beginning of the Scan test, the driver circuit 46 is configured to begin a new Scan test.

Immediately after the time period T_{SOS}, a common bus value time period T_{CM} is generated on the bus 40. The common bus value time period T_{CM} includes a bus symbol T_{SP}, a bus symbol T_{SR}, a bus symbol T_{SE}, and a bus symbol T_{SBP}. During the bus symbol T_{SP}, the at_speed_en value is provided on the bus line 40. During the bus symbol T_{SR}, the SR value is transmitted on the bus line 40. During the bus symbol T_{SE}, the SE value is transmitted on the bus line 40. Thus, each set of test inputs that are transmitted to the communication circuit 44 includes the SE value. Each set of test inputs during the serial shift frame (See FIG. 7A) includes a different one of the SI values (e.g., SI(N−1), SI(N), SI(N+1), the SR value and the same SE value.

During the bus symbol T_{BP}, the BP value is transmitted. The BP value is common to all of the register circuits 14. Thus, each set of test inputs that are transmitted to the communication circuit 44 includes the BP value. Each set of test inputs during the serial shift frame (See FIG. 7A) includes a different one of the SI values (e.g., SI(N−1), SI(N), SI(N+1) and the same BP value.

The values on the bus line 40 and the test inputs and test outputs on the test pins 48(1)-48(4) are synchronized in accordance with the clock signal CLK on the test pin 48(3). In this embodiment, the clock signal CLK is simply the clock signal RFFE CLK passed from the bus pin 80. In other embodiments, the clock signal CLK is generated by the oscillator 90 and synchronized in accordance with the clock signal RFFE CLK. Each bus symbol T_{S} is equal to one clock cycle in this embodiment. The at_speed_en value is transmitted on the pin 48(1) during the bus symbol T_{SR}. Additionally, the SR value is transmitted on the pin 48(1) during the bus symbol T_{SE}. Furthermore, the SE value is transmitted on the pin 48(1) during the bus symbol T_{BP}. The SR value is latched during the negative edge of the clock pulse during the bus symbol T_{BP}. In response, a test pin (not explicitly shown in FIG. 11) that transmits SR_DUT is driven from a high voltage value to a low voltage value. The SE value remains in a high voltage value throughout the mini-telegram. Immediately after the mini-telegram, parallel shift occurs in the combinational logic for the scan test.

FIG. 13 is a graphic diagram providing an exemplary illustration of the Scan test performed by the bus circuit 36B of FIG. 11 in accordance with another embodiment of the present disclosure. Common elements between FIGS. 11 and 13 are shown therein with common element numbers and will not be re-described herein.

The Scan test shows a mini-telegram transmitted after the parallel shift. The mini-telegram has an SOS sequence (labeled SOS) at the beginning that is transmitted during an SOS time period T_{SOP} and common bus values (e.g., at en_speed_en, SR value, SE value, BP1 value, BP2 value) along the along the data line RFFE DATA. The SOS sequence is a sequence that clearly indicates a beginning of a serial shift and is clearly distinguishable from other pulse patterns transmitted on the bus 40. In this embodiment, the clock signal RFFE clock on bus line 82 is held low throughout the entirety of the SOS time period T_{SOP}. Furthermore, a high voltage value V_{HIGH} is transmitted during a time period TDATA. The time period TDATA is equal to half the time period T_{SOP}. Immediately following the time period TDATA is the time period T_{HOLD}. The time period T_{SOSB} is equal to half the time period T_{SOS}. During the time period T_{HOLD}, a low voltage value V_{LOW} is transmitted on the bus line 40. This pattern is distinguishable from any of the other bus patterns on the bus line 40 and the bus line 82. In particular, in no other circumstance except during the beginning of the Scan test (as shown in FIG. 12) is the bus line 82 held low while the bus line 40 held high. As such, this is a clear signal that a Scan test is beginning.

Immediately after the time period T_{SOS}, a common bus value time period T_{CM} is generated on the bus 40. The common bus value time period T_{CM} includes a bus symbol T_{SP}, a bus symbol T_{SR}, a bus symbol T_{SE}, and a bus symbol T_{SBP}. During the bus symbol T_{SP}, the at_speed_en value is provided on the bus line 40. During the bus symbol T_{SR}, the SR value is transmitted on the bus line 40. During the bus symbol T_{SE}, the SE value is transmitted on the bus line 40. Thus, each set of test inputs that are transmitted to the communication circuit 44 includes the SE value. Each set of test inputs during the serial shift frame (See FIG. 7A) includes a different one of the SI values (e.g., SI(N−1), SI(N), SI(N+1), the SR value and the same SE value.

During the bus symbol T_{BP}, the BP value is transmitted. The BP value is common to all of the register circuits 14. Thus, each set of test inputs that are transmitted to the communication circuit 44 includes the BP value. Each set of test inputs during the serial shift frame (See FIG. 7A) includes a different one of the SI values (e.g., SI(N−1), SI(N), SI(N+1) and the same BP value.

The values on the bus line 40 and the test inputs and test outputs on the test pins 48(1)-48(4) are synchronized in accordance with the clock signal CLK on the test pin 48(3). In this embodiment, the clock signal CLK is simply the clock signal RFFE CLK passed from the bus pin 80. In other embodiments, the clock signal CLK is generated by the oscillator 90 and synchronized in accordance with the clock signal RFFE CLK. Each bus symbol T_{S} is equal to one clock cycle in this embodiment. The at_speed_en value is transmitted on the pin 48(1) during the bus symbol T_{SR}. Additionally, the SR value is transmitted on the pin 48(1) during the bus symbol T_{SE}. Furthermore, the SE value is transmitted on the pin 48(1) during the bus symbol T_{BP}. The SR value is latched during the negative edge of the clock pulse during the bus symbol T_{BP}. In response, a test pin (not explicitly shown in FIG. 11) that transmits SR_DUT is driven from a high voltage value to a low voltage value. The SE value remains in a high voltage value throughout the mini-telegram. Immediately after the mini-telegram, serial shift occurs that are input and output for the scan test.

Those skilled in the art will recognize improvements and modifications to the embodiments of the present disclosure. All such improvements and modifications are considered within the scope of the concepts disclosed herein and the claims that follow.

1. A slave circuit comprising:
one or more bus pins coupled to a bus;
a communication circuit coupled to the bus; and
a driver circuit coupled to the one or more bus pins and comprising:
a plurality of test pins coupled to the communication circuit; and
a test driver circuit configured to operate in a test mode during a test cycle,
the test driver circuit is configured to:
receive a start of scan (SOS) sequence on at least one of the one or more bus pins, wherein the SOS sequence indicates a beginning of the test cycle;
receive a scan enable value on at least one of the one or more bus pins during the test cycle;
receive a series of scan inputs over the one of more bus pins during the test cycle; and
generate sets of test inputs, wherein each set of test inputs includes a different one of the series of scan inputs and the scan enable value.

2. The slave circuit of claim 1, wherein:
the communication circuit includes a plurality of sequential state elements; and
each sequential state element of the plurality of sequential state elements is configured to receive a different one of the sets of test inputs.

3. The slave circuit of claim 1, wherein:
the communication circuit further comprising combinational logic; and
the test driver circuit is further configured to receive a series of test outputs, each test output of the series of test outputs resulting from a previous set of test inputs being processed by the combinational logic.

4. The slave circuit of claim 1, wherein:
the one or more bus pins is a single bus pin;
the bus is a single-wire bus; and
the test driver circuit is configured to generate a device clock in accordance with pulses received on the single bus pin and transmit the device clock to the communication circuit.

5. The slave circuit of claim 1, wherein:
the one or more bus pins is a single bus pin;
the bus is a single-wire bus;
the test driver circuit includes an oscillator that generates a clock signal; and
the test driver circuit is configured to generate a device clock in accordance with clock signal from the oscillator and transmit the device clock to the communication circuit.

6. The slave circuit of claim 1, wherein:
the one or more bus pins includes a data pin and a clock pin;
the SOS sequence, the scan enable value, and the sets of test inputs are configured to be received on the data pin;
the clock pin is configured to receive a clock signal; and
the test driver circuit is configured to generate a device clock in accordance with the clock signal and transmit the device clock to the communication circuit.

7. The slave circuit of claim 1, wherein the test driver circuit is configured to operate in the test mode during the test cycle, the test driver circuit is configured to:
receive a scan reset value on at least one of the one or more bus pins during the test cycle; and
generate the sets of test inputs such that each set of test inputs includes the scan reset value.

8. The slave circuit of claim 1, wherein the bus is a single-wire bus and the one or more bus pins are a single bus pin, the bus circuit further comprising:
a switch circuit coupled between the bus pin, the communication circuit, and the test driver circuit; and
a driver controller configured to:
control the switch circuit to decouple the communication circuit from the bus pin and to couple the test driver circuit to the bus pin in response to the SOS sequence; and
control the switch circuit to decouple the test driver circuit from the bus pin and to couple the communication circuit in response to an explicit indication of a communication mode.

9. The slave circuit of claim 8, wherein:
the driver circuit further comprises a test mode pin coupled between the driver controller and the communication circuit; and
the communication circuit is configured to assert the test mode pin to provide the explicit indication of the test mode and de-assert the test mode pin to provide the explicit indication of the communication mode.

10. The slave circuit of claim 9, wherein the communication circuit comprises a mode detector configured to:
assert the test mode pin in response to receiving a test initiation command; and
de-assert the test mode pin in response to power cycling of the bus circuit.

11. The slave circuit of claim 10, wherein the communication circuit comprises a receive circuit coupled to the bus pin and is configured to:
receive the test initiation command in the communication mode via the bus pin; and
provide the test initiation command to the mode detector.

12. A single-wire bus circuit comprising:
a bus pin coupled to a single-wire bus;
a communication circuit coupled to the single-wire bus; and
a driver circuit coupled to the bus pin and comprising:
a plurality of test pins coupled to the communication circuit; and
a test driver circuit configured to operate in a test mode during a test cycle,
the test driver circuit is configured to:
receive a start of scan (SOS) sequence on the bus pin, wherein the SOS sequence indicates a beginning of the test cycle;
receive a scan enable value on the bus pin during the test cycle;
receive a series of scan inputs on the bus pin during the test cycle; and
generate sets of test inputs, wherein each set of test inputs includes a different one of the series of scan inputs and the scan enable value.

13. The single-wire bus circuit of claim 12, wherein:
the communication circuit includes a plurality of sequential state elements; and
each of the sequential state elements is configured to receive a different one of the sets of test inputs.

14. The single-wire bus circuit of claim 12, wherein:
the communication circuit further comprises combinational logic; and
the test driver circuit is further configured to receive a series of test outputs, each test output of the series of test outputs resulting from a previous set of test inputs being processed by the combinational logic.

15. The single-wire bus circuit of claim 12, wherein:
the test driver circuit is further configured to transmit the sets of test inputs to the communication circuit through the plurality of test pins.

16. The single-wire bus of claim 12, wherein the plurality of test pins further includes a scan output pin to receive a scan output from the communication circuit.

17. The single-wire bus circuit of claim 12, further comprising:
a switch circuit coupled between the bus pin, the communication circuit, and the test driver circuit; and
a driver controller configured to:
control the switch circuit to decouple the communication circuit from the bus pin and to couple the test driver circuit to the bus pin in response to the SOS sequence; and
control the switch circuit to decouple the test driver circuit from the bus pin and to couple the communication circuit in response to an explicit indication of a communication mode.

18. The single-wire bus circuit of claim 17, wherein:
the driver circuit further comprises a test mode pin coupled between the driver controller and the communication circuit; and
the communication circuit is configured to assert the test mode pin to provide the explicit indication of the test mode and de-assert the test mode pin to provide the explicit indication of the communication mode.

19. The single-wire bus circuit of claim 18, wherein the communication circuit comprises a mode detector configured to:
assert the test mode pin in response to receiving a test initiation command; and
de-assert the test mode pin in response to power cycling of the bus circuit.

20. The single-wire bus circuit of claim 12, wherein the SOS sequence includes a pulse having a duration of at least two bus symbols.
